(19) United States
(12) Patent Application Publication
(10) Pub. No.: US 2025/0231237 A1
(43) Pub. Date: Jul. 17, 2025

(54) ELECTRONIC DEVICE CAPABLE OF SHARING A MEMORY AND METHOD FOR OPERATING AN ELECTRONIC DEVICE TO SHARE A MEMORY

(71) Applicant: REALTEK SEMICONDUCTOR CORPORATION, HSINCHU (TW)

(72) Inventors: JIA LIN MEI, JIANGSU PROVINCE (CN); HONG CHANG, JIANGSU PROVINCE (CN)

(21) Appl. No.: 18/973,138

(22) Filed: Dec. 9, 2024

(30) Foreign Application Priority Data
Jan. 17, 2024 (CN) 202410069433.6

(51) Int. Cl. G01R 31/319; G01R 31/3193

(52) U.S. Cl. CPC G01R 31/31924; G01R 31/31937

(57) ABSTRACT

The electronic device includes a first chip and a second chip. The first chip includes a first master slave recognition pin coupled to a master voltage, a first access detection pin coupled to a first voltage, and a first interface pin coupled to a memory. The second chip includes a second master slave recognition pin, a second access detection pin coupled to the first access detection pin, and a second interface pin coupled to the first interface pin and the memory. When the first chip is activated, the first chip enters an idle state. When the first chip stays in the idle state for more than a predetermined idle time and the first access detection pin remains at the first voltage, the first chip enters an access state.

### CROSS-REFERENCE TO RELATED APPLICATIONS

This application claims priority of China application No. 202410069433.6, filed on Jan. 17, 2024, which is incorporated by reference in its entirety.

### TECHNICAL FIELD

The present application relates to an electronic device; in particular, to an electronic device capable of sharing a memory between multiple chips.

### BACKGROUND

In light of the increasing demands to the functionality of modern electronic devices, the motherboards of electronic devices often need to be equipped with multiple chips, such as multiple system-on-chips. Since the programs executed by a system-on-chip are usually stored in the memory (such as, a flash memory), the motherboard contains multiple system-on-chips as well as multiple corresponding memories. In some applications, multiple system-on-chips on a motherboard may, in fact, have the same function; that is, they may execute the same program. In this scenario, if each system-on-chip still uses its own memory to store and the execution program, it will greatly increase the hardware cost and power consumption. Therefore, how to enable multiple system-on-chips to access the same memory (i.e., to share the memory) to reduce hardware cost and power consumption is a problem to be solved.

### SUMMARY OF THE INVENTION

One embodiment of the present disclosure discloses an electronic device. The electronic device includes a first chip and a second chip. The first chip includes a first master slave recognition pin coupled to a master voltage, a first access detection pin coupled to a first voltage, and a first interface pin coupled to a memory, wherein the first chip is configured to switch among an idle state, a detection state and an access state according to the voltage of the first master slave recognition pin and the voltage of the first access detection pin. The second chip includes a second master slave recognition pin, a second access detection pin coupled to the first access detection pin, and a second interface pin correspondingly coupled to the first interface pin and the memory, wherein the second chip is configured to switch among the idle state, the detection state and the access state according to the voltage of the second master slave recognition pin and the voltage of the second access detection pin. When the first chip is activated, the first chip enters the idle state, and when the first chip stays in the idle state for more than a predetermined idle time and the first access detection pin remains at the first voltage, the first chip enters the access state so as to access the memory via the first interface pin and fix a voltage of the first access detection pin at a second voltage. The first voltage and the second voltage are different.

Another embodiment of the present disclosure discloses a method for operating an electronic device. The electronic device includes a first chip and a second chip. The first chip includes first master slave recognition pin coupled to a master voltage, a first access detection pin coupled to a first voltage, and a first interface pin coupled to a memory. The second chip includes a second master slave recognition pin, a second access detection pin coupled to the first access detection pin, and a second interface pin correspondingly coupled to the first interface pin and the memory. The method includes when the first chip is activated, causing the first chip to enter an idle state, and when the first chip stays in the idle state for more than a predetermined idle time and the first access detection pin remains at the first voltage, causing the first chip to enter an access state so that the first chip accesses the memory via the first interface pin, and fixing a voltage of the first access detection pin at a second voltage. The first voltage and the second voltage are different.

### BRIEF DESCRIPTION OF THE DRAWINGS

FIG. 1 is a schematic diagram illustrating an electronic device according to one embodiment of the present disclosure.

FIG. 2A and FIG. 2B are flow charts illustrating a method for operating the first chip and second chip of the electronic device according to one embodiment of the present disclosure.

FIG. 3 is a timing diagram illustrating the operation of the electronic device of FIG. 1 according to one embodiment of the present disclosure.

FIG. 4 is a schematic diagram illustrating an electronic device according to a further embodiment of the present disclosure.

FIG. 5 is a timing diagram illustrating the operation of the electronic device of FIG. 4 according to one embodiment of the present disclosure.

FIG. 6 is a timing diagram illustrating the operation of the electronic device of FIG. 1 according to a further embodiment of the present disclosure.

FIG. 7 is a timing diagram illustrating the operation of the electronic device of FIG. 1 according to a further embodiment of the present disclosure.

FIG. 8 is a timing diagram illustrating the operation of the electronic device of FIG. 1 according to a further embodiment of the present disclosure.

FIG. 9 is a timing diagram illustrating the operation of the electronic device of FIG. 1 according to a further embodiment of the present disclosure.

### DETAILED DESCRIPTION

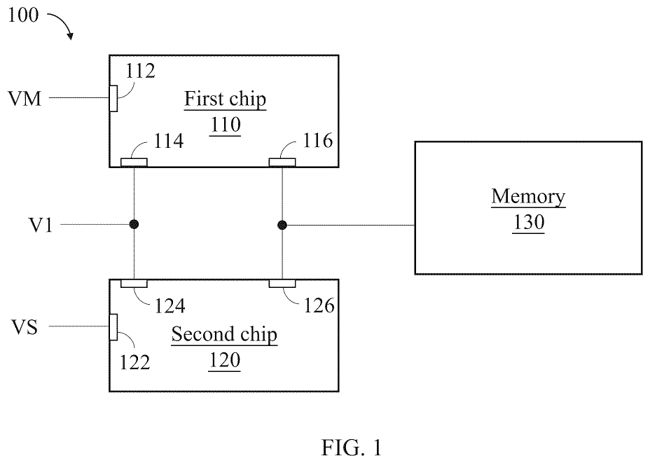

FIG. 1 is a schematic diagram illustrating an electronic device 100 according to one embodiment of the present disclosure. The electronic device 100 includes a first chip 110 and a second chip 120. The first chip 110 and the second chip 120 are coupled to a memory 130. The first chip 110 and the second chip 120 can, for example, include a processor and can access data in the memory 130 in turns (i.e., in the polling manner). The memory 130 can be, for example, a flash memory; however, the present disclosure is not limited thereto.

The first chip 110 may include a first master slave recognition pin 112, a first access detection pin 114 and a first interface pin 116. Similarly, the second chip 120 may include a second master slave recognition pin 122, a second access detection pin 124 and a second interface pin 126. In the present embodiment, the first chip 110 and the second chip 120 can be, for example, two chips with the same functionalities, and in some embodiments, the first chip 110 and the second chip 120 can be two chips with identical structures. In this scenario, in order to allow the first chip 110 and the second chip 120 to access the memory 130 in turns without having conflicts during the process, it is feasible to assign the first chip 110 and second chip as a master chip and a slave chip with different access priorities by providing different voltages to the first master slave recognition pin 112 of the first chip 110 and the second master slave recognition pin 122 of the second chip 120. For example, the first master slave recognition pin 112 of the first chip 110 can be coupled to the master voltage VM, and the second master slave recognition pin 122 of the second chip 120 can be coupled to the slave voltage VS. In such case, the first chip 110 can be the master chip, and the second chip 120 can be the slave chip. In the present embodiment, the master chip may be given a higher priority to access the memory 130 over the slave chip, thus avoiding conflicts between the two. In some embodiments, the master voltage VM can be, for example, a power voltage of the electronic device 100, and the slave voltage VS can be, for example, the ground voltage of the electronic device 100; however, the present disclosure is not limited thereto.

The first access detection pin 114 of the first chip 110 can be coupled to the first voltage V1, and the second access detection pin 124 of the second chip 120 can be coupled to the first access detection pin 114 of the first chip 110. In the present embodiment, the first chip 110 and the second chip 120 may, under certain conditions, change the voltages of the first access detection pin 114 and the second access detection pin 124 by changing the internal wiring; for example, the voltages of the first access detection pin 114 and the second access detection pin 124 can be changed to the second voltage V2 different from the first voltage V1. For example, the first voltage V1 can be the power voltage, whereas the second voltage V2 can be the ground voltage. In the first chip 110, the first access detection pin 114 can be coupled to the second voltage V2 via a switch; thus, when the first chip 110 starts accessing the memory 130, the switch can be conducted, thereby causing the voltages of the first access detection pin 114 and the second access detection pin 124 to be dropped down to the second voltage V2. Consequently, the second chip 120 can determine whether the memory 130 is in a state being accessed according to the voltage of the second access detection pin 124. Similarly, the first chip 110 can determine whether the memory 130 is in a state being accessed according to the voltage of the first access detection pin 114.

In some embodiments, the first master slave recognition pin 112, the first access detection pin 114, the second master slave recognition pin 122 and the second access detection pin 124 can be configured using the General-Purpose Input/Output (GPIO) in the first chip 110 and the second chip 120.

Furthermore, the first interface pin 116 can be coupled to the memory 130, and the second interface pin 126 can be coupled to the first interface pin 116 and the memory 130 correspondingly. Although in FIG. 1, the first interface pin 116 and the second interface pin 126 are represented by only one pin each, the present disclosure is not limited thereto. In some embodiments, the first chip 110 and the second chip 120 may communicate with the memory 130 via a Serial Peripheral Interface (SPI). In such case, the first interface pin 116 may include input data pins, output data pins, clock pins, and a chip select pin required by the Serial Peripheral Interface, as may the second interface pin 126.

In the present embodiment, the first chip 110 can switch among an idle state, a detection state and an access state according to the voltages of the first master slave recognition pin 112 and the first access detection pin 114, also, the second chip 120 can switch among the idle state, the detection state and the access state according to the voltages of the second master slave recognition pin 122 and the second access detection pin 124.

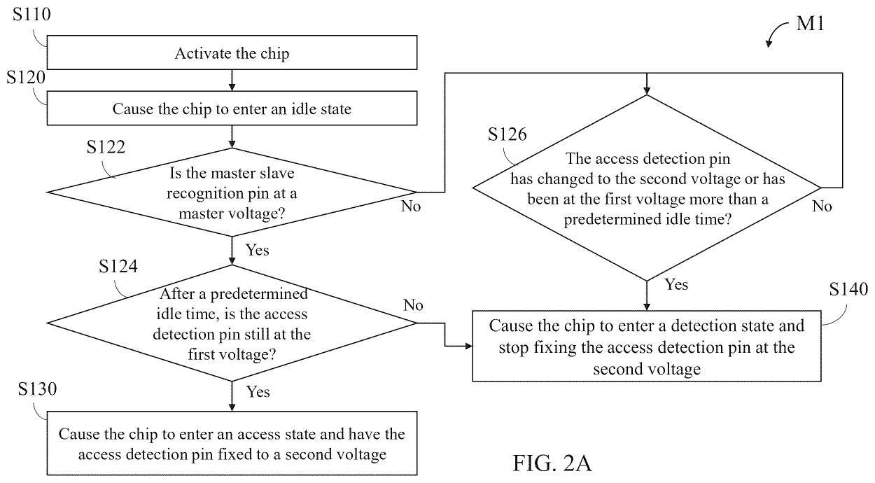

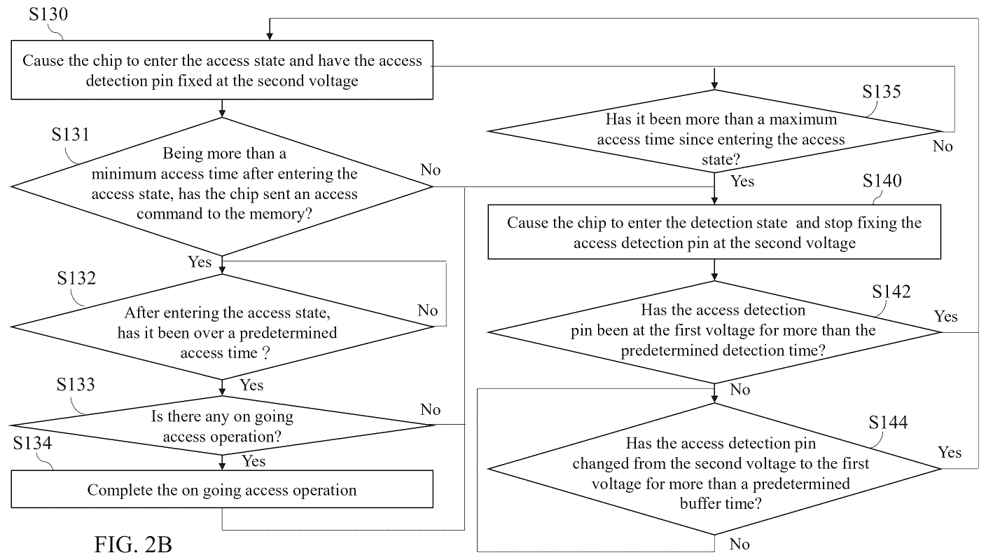

In the present embodiment, FIG. 2A and FIG. 2B are flow charts illustrating a method M1 for operating the first chip 110 and the second chip 120 of the electronic device 100 according to one embodiment of the present disclosure. The method M1 may include Steps S110 to S144. In the present embodiment, the first chip 110 and the second chip 120 can be switched among the idle state, the detection state and the access state according to the processes shown in FIG. 2A and FIG. 2B. Furthermore, in some embodiments, the first chip 110 and the second chip 120 may include a state machine, and the first chip 110 and the second chip 120 may change its state via the state machine.

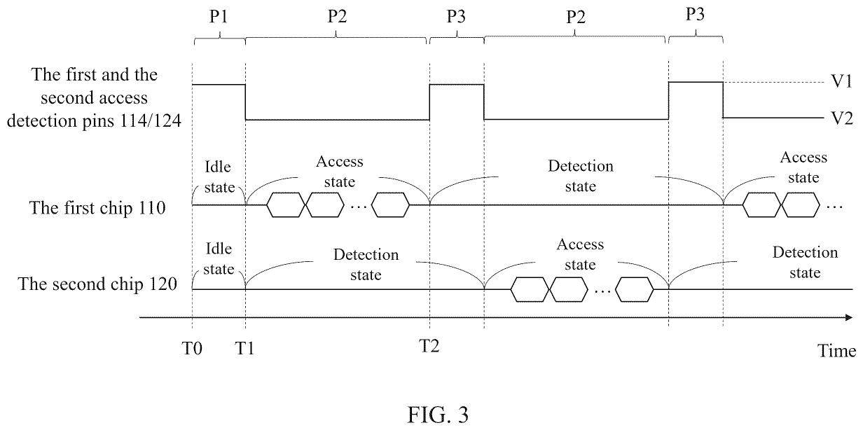

FIG. 3 is a timing diagram illustrating the operation of electronic device 100 according to one embodiment of the present disclosure. In FIG. 3, the first chip 110 and the second chip 120 may be activated at the time point TO (Step S110), and at this point, the first chip 110 and the second chip 120 enter the idle state (Step S120).

Next, since the master slave recognition pin 112 of the first chip 110 is coupled to the master voltage VM, in Step S122, the first chip 110 is guided to Step S124. In contrast, in Step S122, the second chip 120 is guided to Step S126. In this scenario, since the first chip 110 and the second chip 120 are both in the idle state, the access detection pins 114 and 124 both remain at the first voltage V1, such that in Step S124, it is determined that the first chip 110 enters the access state (Step S130), and in Step S126, it is determined that the second chip 120 enters the detection state (Step S140).

In other words, as shown in FIG. 3, the first chip 110 will be determined as the master chip, whereas when the first chip 110 stays in the idle state for more than a predetermined idle time P1 and the first access detection pin 114 remains at the first voltage V1, the first chip 110 will enter the access state. In the access state, the first chip 110 can access the memory 130 via the first interface pin 116, and can fix the voltage of the first access detection pin 114 at the second voltage V2, so as to indicate that the memory 130 is being occupied.

In contrast, the second chip 120 will be determined as the slave chip, and, as shown in FIG. 3, in the idle state, when the second access detection pin 114 has remained at the first voltage V1 for more than the predetermined idle time P1, the second chip 120 will enter the detection state. In some embodiments, if the first chip 110 is activated earlier than the second chip 120, then the second chip 120 may detect that the voltage of the second access detection pin 124 changes from the first voltage V1 to the second voltage V2 before the predetermined idle time P1 ends, and in this instance, the second chip 120 can enter the detection state early.

In FIG. 3, the first chip 110 enters the access state at the time point T1 and starts accessing data in the memory 130. When the first chip 110 enters the access state for more than a predetermined access time P2 (Step S132), the first chip 110 can determine whether there is any ongoing access operation (Step S133); if yes, then it will enter the detection state after the ongoing access operation completes (Step S134); if not, then the first chip 110 can directly enter the detection state after Step S133. When the first chip 110 enters the detection state, it stops fixing the voltage of the first access detection pin 114 at the second voltage V2. In other words, the voltages of the first access detection pin 114 and the second access detection pin 116 will return to the first voltage V1.

Furthermore, in some cases, if the first chip 110 enters the access state for more than minimum access time, and the first chip 110 has not sent an access command to the memory 130 (Step S131), it means that the first chip 110 may have an error or there is no need to access the memory 130; in this instance, the first chip 110 can directly return to the detection state and stop fixing the voltage of the first access detection pin 114 at the second voltage V2, thereby allowing another chip, such as the second chip 120, to access the memory 130.

Further, in some cases, if the first chip 110 enters the access state for more than a maximum access time, and the first chip 110 has not stopped fixing the voltage of the first access detection pin 114 at the second voltage V2, it means that the first chip 110 may have an error, and in this instance, the first chip 110 can be forced to enter the detection state (Step S135) and stop fixing the voltage of the first access detection pin 114 at the second voltage V2, thereby allowing another chip, such as the second chip 120, to access the memory 130. In FIG. 2B, Steps S131 to S134 can be executed in parallel with Step S135, and if, in Steps S131, S133 and S134, it has determined that the first chip must enter the detection state (i.e., proceeds to the Step S140), then there is no need to execute Step S135 and the calculation of whether the maximum access time is exceeded can be terminated.

In FIG. 3, after entering the access state for more than the predetermined access time P2, the first chip 110 enters the detection state at the time point T2, and the voltages of the first access detection pin 114 and the second access detection pin 124 will change from the second voltage V2 back to the first voltage V1. According to the conditions set by Step S144, the second chip 120 will enter the access state to access the memory 130 after the voltage of the second access detection pin 124 changes from the second voltage V2 to the first voltage V1 for more than a predetermined buffer time P3, and fix the voltage of the second access detection pin 124 at the second voltage V2.

Next, when the second chip 120 enters the access state for more than the predetermined access time P2, it may continue to complete the last access operation depending on the actual need (Steps S132, S133 and S134) and then re-enter the detection state, and stop fixing the voltage of the second access detection pin 124 at the second voltage V2. When the first chip 110 detects that the voltage of the first access detection pin 114 changes from the second voltage V2 to the first voltage V1 for more than the predetermined buffer time P3, it can re-enter the access state to access the memory 130 and fix the voltage of the first access detection pin 114 at the second voltage V2. Consequently, the first chip 110 and the second chip 120 can access the memory 130 in turns without having conflicts.

In some embodiments, if the first chip 110 detects that the voltage of the first access detection pin 114 has changed from the first voltage V1 to the second voltage V2 for more than a burning time (such as, after several seconds) after entering the detection state, it may imply that the second chip 120 may execute a burning operation to the memory 130 during the process of accessing the memory 130 so as to write in new execution program; in this instance, the first chip 110 can immediately execute a reset operation when detecting that the voltage of the first access detection pin 114 changes from the second voltage V2 to the first voltage V1, so as to update the program should be executed by the first chip 110.

Furthermore, in some embodiments, the first chip 110 and the second chip 120 may include one or more timers, by which the first chip 110 and the second chip 120 may start timing after entering the idle state, access state and detection state, so as to determine whether or not a time for each of the various state switching conditions shown in FIG. 2A and FIG. 2B has been reached, such as the predetermined idle time P1, the predetermined access time P2, and the predetermined buffer time P3.

According to the processes shown in FIG. 2A and FIG. 2B, the method M1 can avoid the conflicts between the first chip 110 and the second chip 120 in the electronic device 100 under various conditions.

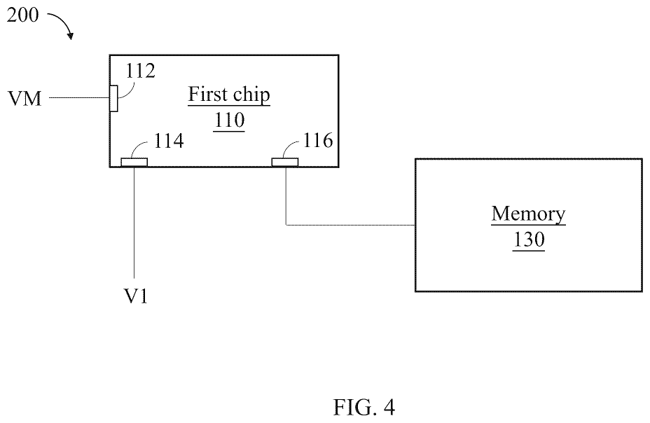

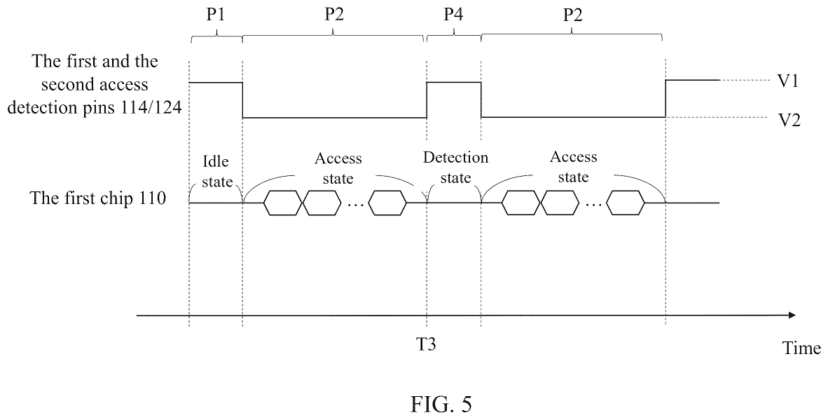

FIG. 4 is a schematic diagram illustrating an electronic device 200 according to another embodiment of the present disclosure, and FIG. 5 is a timing diagram illustrating the operation of the electronic device 200 according to one embodiment of the present disclosure. In the present embodiment, the electronic device 200 and the electronic device 100 differ in that the electronic device 200 includes only the first chip 110 but does not include the second chip 120. In this scenario, as shown in FIG. 5, after the first chip 110 enters the access state (Step S130), it will complete the ongoing access operation depending on the actual need after the passing of the predetermined access time P2 (Steps S132, S133 and S134) and enter the detection state at the time point T3; however, in the detection state, since the electronic device 200 does not have other chips capable of accessing the memory 130, the first chip 110, after the voltage of the access detection pin 114 is remained at the first voltage V1 for more than a predetermined detection time P4 (Step S142), would re-enter the access state (Step S130) and accesses the memory 130 again. In some embodiments, the predetermined buffer time P3 may be much smaller than the predetermined detection time P4. For example, the predetermined buffer time P3 may be a number of cycles of the clock signal used by the first chip 110 or the second chip 120, while the predetermined detection time P4 may be several microseconds.

In some embodiments, when it is determined that there is only the first chip 110 in the electronic device 200 that will access the memory 130, the length of the predetermined detection time P4 can be set to be shorter, so that the efficiency of the first chip 110 accessing the memory 130 can be improved.

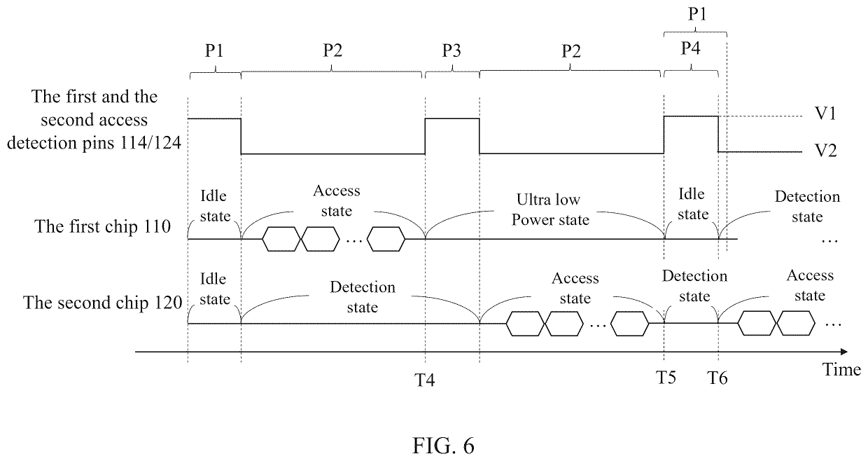

FIG. 6 is a timing diagram illustrating the operation of the electronic device 100 according to another embodiment of the present disclosure. In FIG. 6, after the first chip 110 is activated and accesses the memory 130, it enters an ultra-low power state (e.g., a sleep state) at time point T4 and there is no longer a need to access the memory 130, and thus the second chip 120 enters the access state from the detection state after the second access detection pin 124 changes from the second voltage V2 to the first voltage V1 for a predetermined buffer time P3. Then, when the second chip 120 has entered the access state for more than the predetermined access time P2 and has completed the access operation, it will return to the detection state. In the case that the first chip 110 has not left the ultra-low power state, the second access detection pin 124 will remain at the first voltage V1, and the second chip 120 will wait for the predetermined detection time P4 in the detection state before entering the access state again. However, in the embodiment of FIG. 6, the first chip 110 happens to be activated at the time T5 when the second chip 120 enters the detection state.

According to the flow of FIG. 2A, when the first chip 110 is activated, the first chip 110 will first enter the idle state (Step S120) and wait for the predetermined idle time P1 to confirm that the voltage of the first access detection pin 114 is maintained at the first voltage V1 before entering the access state (Step S124). In the present embodiment, since the predetermined idle time P1 is greater than the predetermined detection time P4, the second chip 120 will enter the access state from the detection state first at the time point T6 after the predetermined detection time P4 and change the voltage of the second access detection pin 124 from the first voltage V1 to the second voltage V2. Correspondingly, the first chip 110 enters the detection state (Step S124). Then the first chip 110 and the second chip 120 can take turns to access the memory 130 according to the timing diagram in FIG. 3 without any conflict.

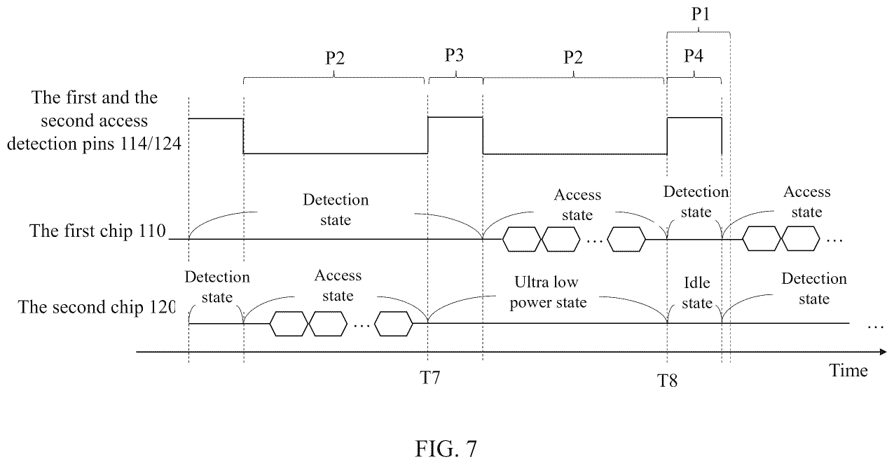

FIG. 7 is a timing diagram illustrating the operation of the electronic device 100 according to another embodiment of the present disclosure. In the embodiment of FIG. 7, the second chip 120 enters an ultra-low power state during operation and no longer needs to access the memory 130, so it leaves the access state at time point T7 and stops fixing the voltage of the second access detection pin 124 at the second voltage V2. In this scenario, the first chip 110 changes from the detection state to the access state after the voltage of the first access detection pin 114 is changed from the second voltage V2 back to the first voltage V1 for the predetermined buffer time P3, and starts to access the memory 130 and fixes the voltage of the first access detection pin 114 at the second voltage V2. Next, when the first chip 110 enters the access state for more than the predetermined access time P2 and has completed the access operation, it returns to the detection state and stops fixing the voltage of the first access detection pin 114 at the second voltage V2.

In the embodiment of FIG. 7, the second chip 120 is reactivated and leaves the ultra-low power state at the time point T8 after the first chip 110 enters the detection state. In this scenario, according to process of FIG. 2A, the second chip 120 can enters the idle state after being activated, and since the predetermined idle time P1 is greater than the predetermined detection time P4, the first chip 110 will enter the access state first and fix the voltage of the first access detection pin 114 at the second voltage V2, whereas the second chip 120 will enter the detection state correspondingly (Step S126). Next, the first chip 110 and the second chip 120 can take turns to access the memory 130 according to the operation illustrated in the timing diagram FIG. 3 without having conflicts.

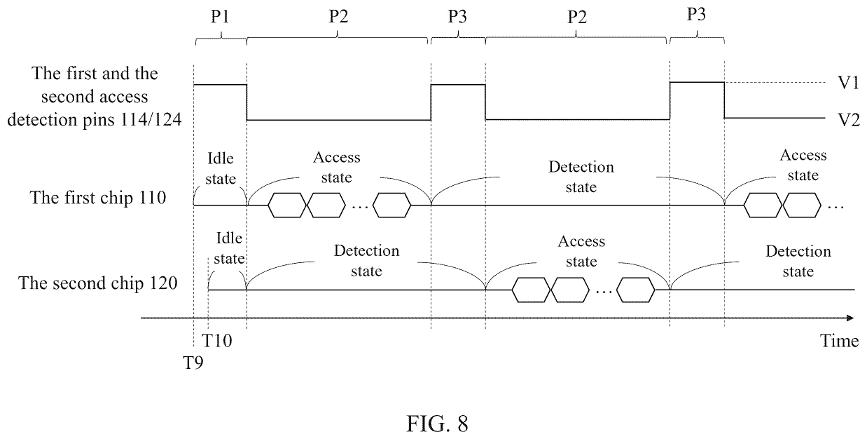

FIG. 8 is a timing diagram illustrating the operation of the electronic device 100 according to another embodiment of the present disclosure. In FIG. 8, the first chip 110 is activated at the time point T9, and the second chip 120 is activated at the time point T10 after the time point T9. In this scenario, the first chip 110 will preferentially enter the access state from the idle state (Step S124), and the second chip 120 will, in the idle state, detect that the voltage of the second access detection pin 124 changes from the first voltage V1 to the second voltage V2; thus, the second chip 120 enters the detection state after the first chip 110 enters the access state (Step S126). Next, the first chip 110 and the second chip 120 can take turns to access the memory 130 according to the operation illustrated in the timing diagram FIG. 3 without having conflicts.

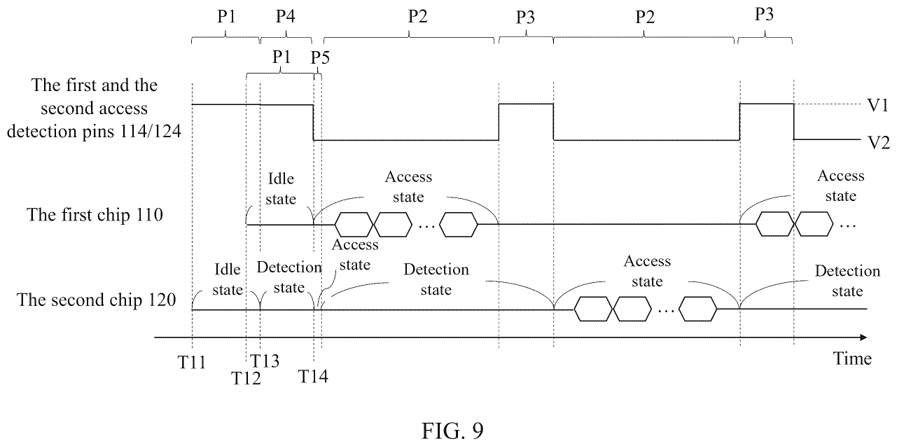

FIG. 9 is a timing diagram illustrating the operation of the electronic device 100 according to another embodiment of the present disclosure. In FIG. 9, the second chip 120 is activated at the time point T11, and the first chip 110 is activated at the time point T12 after the time point T11. In the present embodiment, the difference between the time point T11 and the time point T12 happens to equal to the predetermined detection time P4. In this scenario, after the second chip 120 enters the idle state, it will enter the detection state at the time point T13 after waiting for the predetermined idle time P1, and enters the access state at the time point T14 (Step S142) after waiting for the predetermined detection time P4 in the detection state. However, since the first chip 110 is activated at a time point after the second chip 120 is activated and the predetermined detection time P4 has elapsed, after the first chip 110 waits for the predetermined idle time P1 in the idle state, it will also enter the access state at the time point T14 (Step S124).

In other words, in the embodiment of FIG. 9, the first chip 110 and the second chip 120 may enter the access state simultaneously at the time point T14. In order to avoid such a conflict, the electronic device 100 may cause the slave chip to wait for an additional slave buffer time (e.g., a few nanoseconds) when entering the access state and make sure that none of the enabling pins of the memory 130 has been changed during the slave buffer time, i.e., making sure that no other chip has accessed the memory 130 during the slave buffer time, and then formally start accessing the memory 130.

For example, the second chip 120 waits for the slave buffer time P5 from the time point T14, and if the voltage of the enabling pins of the memory 130 does not change during the slave buffer time P5, it means that there is no other chip accessing the memory 130, then the second chip 120 will pull down the voltage of the enabling pins of the memory 130 and start accessing the memory. However, in FIG. 9, since the first chip 110 (the master chip) will start accessing the memory 130 directly after entering the access state and will pull down the voltage of the enabling pins of the memory 130, the second chip 120 will detect that the voltage of the enabling pins of the memory 130 has been changed during the slave buffer time P5, and therefore the second chip 120 will not further access the memory 130 and will change from the access state back to the detection state. As a result, conflicts between the first chip 110 and the second chip 120 in accessing the memory 130 can be avoided.

In view of the foregoing, the electronic device and the method for operating the electronic device provided in the embodiments of the present application can allow two chips to access the same memory in turn without conflict by simply setting up the master-slave identification pin and the access detection pin on the chips and operating them in accordance with a specific process. This reduces the hardware cost and power consumption of the electronic device without taking up too many chip pins.

What is claimed is:

1. An electronic device, comprising:
a first chip coupled to a memory, the first chip comprising a first master slave recognition pin coupled to a master voltage, a first access detection pin coupled to a first voltage, and a first interface pin coupled to the memory, wherein the first chip is configured to switch among an idle state, a detection state and an access state according to the voltage of the first master slave recognition pin and the voltage of the first access detection pin; and
a second chip coupled to the memory, the second chip comprising a second master slave recognition pin, a second access detection pin coupled to the first access detection pin, and a second interface pin correspondingly coupled to the first interface pin and the memory, wherein the second chip is configured to switch among the idle state, the detection state and the access state according to the voltage of the second master slave recognition pin and the voltage of the second access detection pin;
wherein:
when the first chip is activated, the first chip enters the idle state; and
when the first chip stays in the idle state for more than a predetermined idle time and the first access detection pin remains at the first voltage, the first chip enters the access state so as to access the memory via the first interface pin and fix a voltage of the first access detection pin at a second voltage; and
the first voltage and the second voltage are different.

2. The electronic device according to claim 1, wherein:
when the first chip enters the access state for more than a predetermined access time and the first chip has completed an ongoing access operation, the first chip enters the detection state and stops fixing the voltage of the first access detection pin at the second voltage.

3. The electronic device according to claim 2, wherein:
when the first chip enters the detection state for more than a predetermined detection time and the voltage of the first access detection pin remains at the first voltage, the first chip re-enters the access state and fixes the voltage of the first access detection pin at the second voltage.

4. The electronic device according to claim 3, wherein the predetermined idle time is greater than the predetermined detection time.

5. The electronic device according to claim 2, wherein:
when it is detected that the voltage of the first access detection pin changes from the second voltage to the first voltage after the first chip enters the detection state for more than a burning time, the first chip executes a reset operation to update a program executed by the first chip.

6. The electronic device according to claim 1, wherein:
the second master slave recognition pin is coupled to a slave voltage different from the master voltage;
when the second chip is activated, the second chip enters the idle state; and
when the second chip stays in the idle state for more than the predetermined idle time and the second access detection pin is at the first voltage, or when the second chip detects that the voltage of the second access detection pin changes from the first voltage to the second voltage during the idle state, the second chip enters the detection state.

7. The electronic device according to claim 6, wherein:
during the detection state, when the voltage of the second access detection pin changes from the second voltage to the first voltage for more than a predetermined buffer time, the second chip enters the access state to access the memory and fix the voltage of the second access detection pin at the second voltage.

8. The electronic device according to claim 6, wherein:
when the second chip enters the access state for more than a slave buffer time and a voltage of an enabling pin of the memory is not changed, the second chip starts accessing the memory.

9. The electronic device according to claim 1, wherein:
when the first chip enters the access state for more than a minimum access time and the first chip has not sent an access command to the memory, the first chip enters the detection state and stops fixing the voltage of the first access detection pin at the second voltage.

10. The electronic device according to claim 1, wherein:
when the first chip enters the access state for more than a maximum access time, the first chip enters the detection state and stops fixing the voltage of the first access detection pin at the second voltage.

11. A method for operating an electronic device, wherein the electronic device comprises a first chip coupled to a memory and a second chip coupled to the memory, wherein the first chip comprises a first master slave recognition pin coupled to a master voltage, a first access detection pin coupled to a first voltage, and a first interface pin coupled to the memory, the second chip comprises a second master slave recognition pin, a second access detection pin coupled to the first access detection pin, and a second interface pin correspondingly coupled to the first interface pin and the memory, wherein the method comprises:
when the first chip is activated, causing the first chip to enter an idle state; and
when the first chip stays in the idle state for more than a predetermined idle time and the first access detection pin remains at the first voltage:
causing the first chip to enter an access state so that the first chip accesses the memory via the first interface pin; and
fixing a voltage of the first access detection pin at a second voltage;
wherein the first voltage and the second voltage are different.

12. The method according to claim 11, further comprising:
when the first chip enters the access state for more than a predetermined access time and the first chip has completed an ongoing access operation, causing the first chip to enter a detection state and stop fixing the voltage of the first access detection pin at the second voltage.

13. The method according to claim 12, further comprising:
when the first chip enters the detection state for more than a predetermined detection time and the voltage of the first access detection pin remains at the first voltage:
causing the first chip to re-enter the access state; and
fixing the voltage of the first access detection pin at the second voltage.

14. The method according to claim 13, wherein the predetermined idle time is greater than the predetermined detection time.

15. The method according to claim 12, further comprising:
when it is detected that the voltage of the first access detection pin changes from the second voltage to the first voltage after the first chip enters the detection state for more than a burning time, causing the first chip to execute a reset operation to update a program executed by the first chip.

16. The method according to claim 11, wherein the second master slave recognition pin is coupled to a slave voltage different from the master voltage, and the method further comprises:
when the second chip is activated, the second chip enters the idle state; and
when the second chip stays in the idle state for more than the predetermined idle time and the second access detection pin is at the first voltage, or when the second chip detects that the voltage of the second access detection pin changes from the first voltage to the second voltage during the idle state, causing the second chip to enter a detection state.

17. The method according to claim 16, wherein:
when the voltage of the second access detection pin changes from the second voltage to the first voltage for more than a predetermined buffer time during the detection state, causing the second chip to enter the access state so as to access the memory and fix the voltage of the second access detection pin at the second voltage.

18. The method according to claim 16, wherein:
when the second chip enters the access state for more than a slave buffer time and the voltage of an enabling pin of the memory is not changed, causing the second chip to start accessing the memory.

19. The method according to claim 11, wherein:
when the first chip enters the access state for more than a minimum access time and the first chip has not sent an access command to the memory, causing the first chip to enter the detection state and stop fixing the voltage of the first access detection pin at the second voltage.

20. The method according to claim 11, wherein:
when the first chip enters the access state for more than a maximum access time, causing the first chip to enter the detection state and stop fixing the voltage of the first access detection pin at the second voltage.
